(19) United States
(12) Patent Application Publication
(10) Pub. No.: US 2026/0247973 A1
(43) Pub. Date: Aug. 20, 2026

(54) SEMICONDUCTOR PACKAGE STRUCTURE AND MANUFACTURING METHOD THEREOF

(71) Applicant: Taiwan Semiconductor Manufacturing Company, Ltd., Hsinchu (TW)

(72) Inventors: Hsin-Jung Chu, Taipei City (TW); Chien-Chang Lin, New Taipei City (TW); Sheng-Han Tsai, Hsinchu (TW); Wei Wu, Hsinchu (TW); Tsung-Yu Chen, Hsinchu City (TW)

(73) Assignee: Taiwan Semiconductor Manufacturing Company, Ltd., Hsinchu (TW)

(21) Appl. No.: 19/055,473

(22) Filed: Feb. 17, 2025

(51) Int. Cl. H01L 23/00; H01L 21/48; H01L 23/367; H01L 23/538; H01L 25/16; H05K 1/18; H10B 80/00; H10D 80/30

(52) U.S. Cl. CPC H10W 42/121; H10W 70/093; H10W 70/611; H10W 90/401; H05K 1/181; H10B 80/00; H10D 80/30; H10W 40/228; H10W 74/15; H10W 90/00; H10W 90/288; H10W 90/724; H10W 90/734

(57) ABSTRACT

A semiconductor package structure includes a package substrate, a packaging component and an affixture structure. The package substrate has a first surface, a second surface opposite to the first surface and a side surface connecting the first surface and the second surface. The packaging component is disposed on the first surface of the package substrate and electrically connected to the package substrate. The affixture structure is affixed to a peripheral portion of the package substrate, wherein the affixture structure at least contacts the side surface and one surface of the first surface and the second surface of the package substrate.

### BACKGROUND

In packaging of semiconductor devices, after individual semiconductor dies are manufactured and packaged, the packaged semiconductor devices may be mounted on a package substrate with other electronic components, such as other semiconductor dies, to form a semiconductor package structure. The semiconductor package structure having semiconductor dies mounted thereon are then bonded to a printed circuit board through a thermal process. Warpage and stress may occur during the thermal process due to the mismatch in Coefficient of Thermal Expansion (CTE) between different materials and different package components, such as different material between the package substrate and the semiconductor dies. The warpage may lead to shorting between connectors of the package substrate and/or open circuit between the connectors and the printed circuit board. It is desired to reduce the warpage of the semiconductor package structure when bonding to the printed circuit board.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are schematic cross-sectional views and top views illustrating various stages of a manufacturing method of a semiconductor package in accordance with some embodiments of the disclosure.

FIGS. 2A-2G are schematic cross-sectional views and top views illustrating various stages of a manufacturing method of a semiconductor package in accordance with some embodiments of the disclosure.

FIG. 3 and FIG. 4 are schematic cross-sectional views illustrating package structures in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10°. The word “substantially” does not exclude “completely” e.g., a composition which is “substantially free” from Y may be completely free from Y.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In semiconductor industry, various chip packages or electronic components may be mounted on a package substrate to form a semiconductor package structure. The semiconductor package structure may then be bonded to a printed circuit board (PCB) through a thermal process. Usually, the chip packages and the package substrate are formed of different materials having mismatched coefficient of thermal expansion (CTE). As a result, the chip packages and the package substrate experience significantly different dimensional change under temperature change. If uncompensated, the disparity in CTE can result in warpage of the semiconductor package structure be it under room temperature or during the thermal process while bonding to a PCB. The effect of mismatch in the CTE is more pronounced with increase in dimension of the chip package, therefore the degree of warpage may be different along different direction. For example, the semiconductor package structure may be warped to a greater degree along the length direction of the chip package than along the width direction of the chip package. Depending on the mismatch of CTE, the warped semiconductor package structure may be concave (i.e., the middle portion of the warped semiconductor package structure is lower than the edge portion of the warped semiconductor package structure) or convex (i.e., the middle portion of the warped semiconductor package structure is higher than the edge portion of the warped semiconductor package structure).

Regarding the warpage issues of the semiconductor package structure, a supporting structure may be attached to one side of the package substrate, and the supporting structure is fixed to the package substrate through an adhesive layer. However, other issues related with the dispensing amounts of the adhesive layer and CTE mismatch between various materials may have reverse impact on warpage control. The present disclosure utilizes an affixture structure to counterbalance the warpage of the semiconductor package structure without using an adhesive.

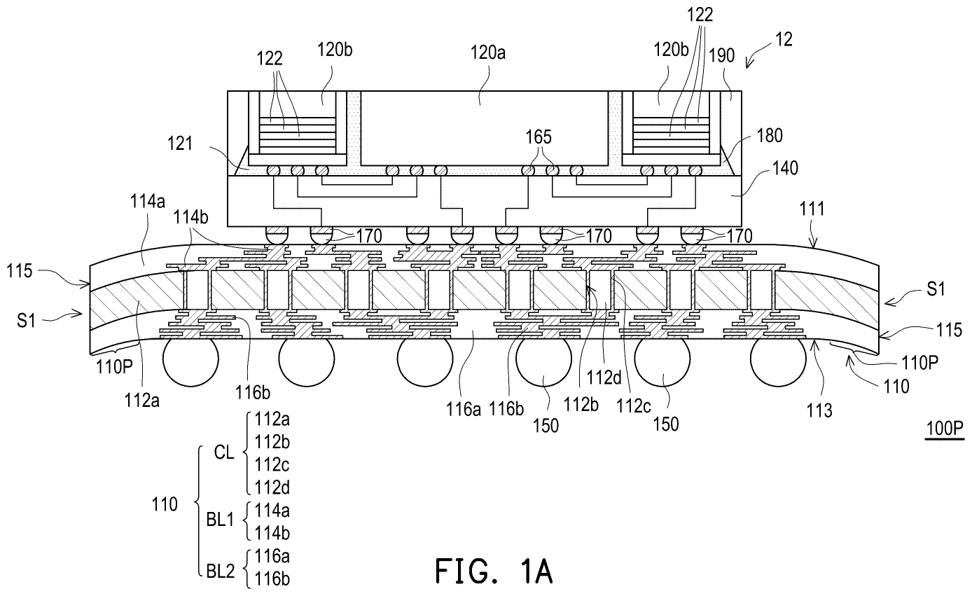

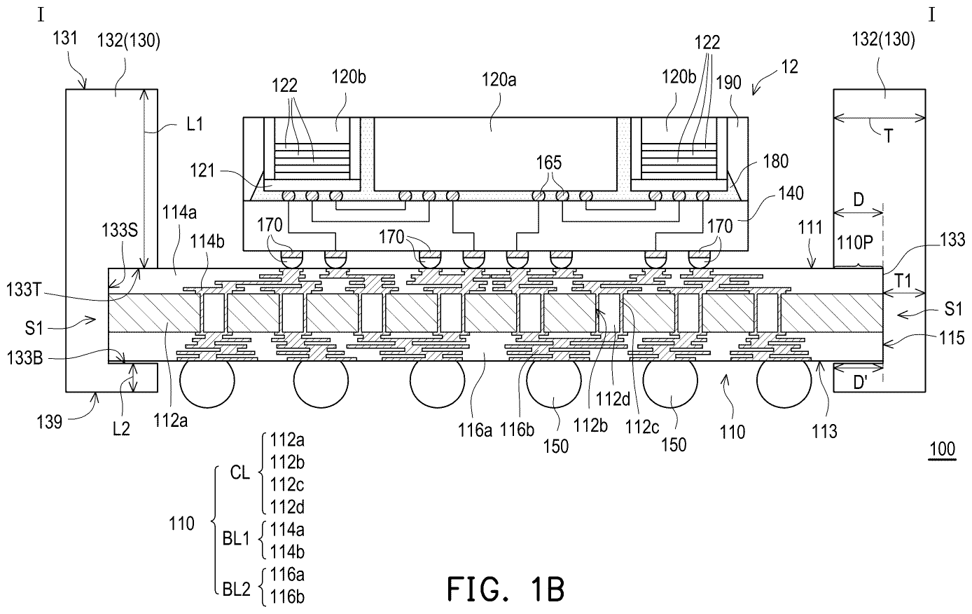

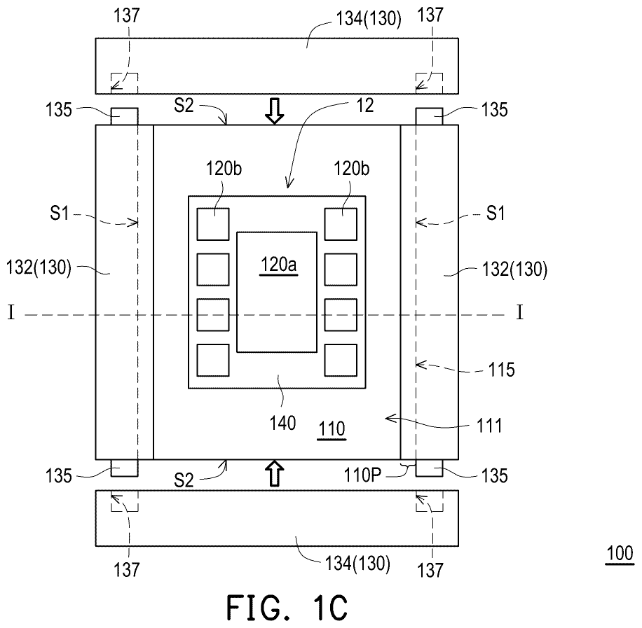

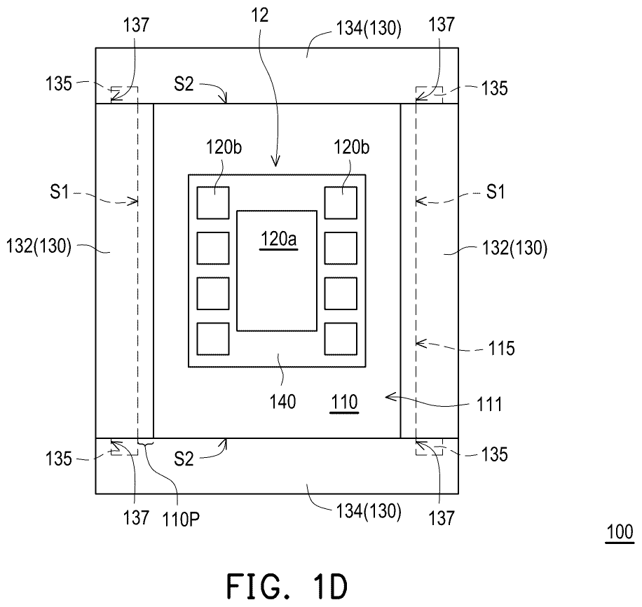

FIGS. 1A-1D are schematic cross-sectional views and top views illustrating various stages of a manufacturing method of a semiconductor package in accordance with some embodiments of the disclosure. FIG. 1B is an exemplary cross-sectional view along the cross-sectional line I-I in FIG. 1C. In FIG. 1C, another portion of the affixture structure is assembling to one portion of the affixture structure that has been fitted onto the package substrate. For simplification purposes, certain component such as the insulating encapsulation may be omitted in FIG. 1C and FIG. 1D. Throughout the various views and illustrative embodiments, like or the same reference numbers are used to designate like or substantially the same elements.

Referring to FIG. 1A, a package substrate 110 is provided, and one or more package components 12 are mounted and bonded to the package substrate 110 to form a semiconductor package structure 100P. The package component 12 is disposed on the package substrate 110 and electrically connected to the package substrate 110 through conductive terminals 170. In some embodiments, as shown in FIG. 1A, the semiconductor package structure 100P is slightly warped and exhibits a frowning-convex warpage form. It is understood that the warpage level shown in FIG. 1A is merely exemplary and various warpage levels including symmetrical or unsymmetrical warpage over the whole package substrate may be presented.

Referring to FIG. 1A, in some embodiments, the package substrate 110 has a first surface 111, a second surface 113 opposite to the first surface 111 and lateral side surface(s) 115 connecting the first surface 111 and the second surface 113. Taking a tetragonal or rectangular shape substrate as an example, referring to both FIG. 1A and FIG. 1C, the package substrate 110 has two opposing first sides S1 and two opposing second sides S2 connecting the two opposing first sides S1. In FIG. 1C, the left side and the right side of the package substrate 110 are regarded as the two opposing first sides S1, and the top side and the bottom side of the package substrate 110 are regarded as the two opposing second sides S2. It is understood that the package substrate may be in other shapes including round, oval or polygonal shapes.

In some embodiments, referring to FIG. 1A, the package substrate 110 includes at least a core layer CL and build-up layers BL1, BL2 disposed on opposite sides of the core layer CL. The core layer CL may include a core material layer 112a with through holes 112b penetrating through the core material layer 112a and through vias 112c formed inside the through holes 112b. For example, the through holes 112b may be lined with a metal or metallic material to form the through vias 112c. In some embodiments, the through vias 112c only partially fill the through holes 112b, and a dielectric filling 112d is formed to fill up the individual through hole 112b. In some alternative embodiments, the through holes 112b are filled by the through vias 112c. In some embodiments, the build-up layers BL1 or BL2 respectively include at least one dielectric layer 114a or 116a (or multiple sublayers) and conductive patterns 114b or 116b embedded in the corresponding dielectric layer 114a or 116a. In some embodiments, the build-up layers BL1, BL2 may independently include more dielectric layers 114a, 116a and more or less conductive patterns 114b, 116b than what is illustrated in FIG. 1A, according to the routing requirements. In some embodiments, the package substrate 110 provide double-sided electrical connection through the conductive patterns 114b, 116b of the build-up layers BL1, BL2 and the through vias 112c that establish electrical connection between the conductive patterns 114b of one build-up layer BL1 with the conductive patterns 116b of the other build-up layer BL2.

In some embodiments, the package substrate 110 is or includes a circuit substrate with a core layer, i.e. a core substrate. The core layer may provide rigidity for the package substrate 110. In some embodiments, the core layer includes, for example, a glass layer, a laminate of fiberglass reinforced BT (bismaleimide-triazine) resins or fiberglass reinforced epoxy resins, or an organic polymer material such as epoxy resins, polyimide (PI), benzocyclobutene (BCB), or polybenzoxazole (PBO). Other suitable dielectric materials are within the contemplated scope of disclosure. In alternative embodiments, the package substrate 110 is or includes a core-less circuit substrate. In some embodiments, the build-up layers BL1, BL2 may be formed of several dielectric sublayer(s) made of any suitable materials, including polymeric materials, composite materials, liquid crystal polymers (LCPs), epoxy laminates of fiberglass sheets, Prepreg, and resins including Ajinomoto build-up film (ABF), or combinations thereof. In some embodiments, the package substrate 110 may include a solder resist layer (not shown) to expose portions of the topmost conductive patterns 114b and bottommost conductive patterns 116b of the package substrate 110 for further electrical connection. The solder resist layer may function to prevent undesirable solder bridges (e.g., unintended electrical connections) among closely spaced metal features.

In some embodiments, connective terminals 150 are formed on the build-up layer BL2 at the opposite side of the package substrate 110 with respect to the package component 12. The connective terminals 150 are in direct contact with the conductive patterns 116b of the package substrate 110. The connective terminals 150 may allow the package substrate 110 to be securely mounted on a board substrate such as a printed circuit board (PCB) and electrically coupled to the board substrate. In some embodiments, the connective terminals 150 include copper pillars, copper bumps, solder bumps or solder balls for ball grid array mounts. In some embodiments, the connective terminals 150 are electrically connected to the package component 12 via the package substrate 110.

Referring to FIG. 1A and FIG. 1C, the package component 12 includes an interposer 140, at least one first semiconductor component 120a disposed on the interposer 140, and several second semiconductor components 120b arranged beside the first semiconductor component 120a and disposed on the interposer 140. The first semiconductor component 120a is spaced apart from the second semiconductor components 120b and located between the second semiconductor components 120b. The first semiconductor component(s) 120a and the second semiconductor component(s) 120b are electrically connected with the interposer 140 through the connectors 165, and the first semiconductor component(s) 120a and the second semiconductor component(s) 120b are electrically connected through the interposer 140. In FIG. 1C, in some embodiments, within the span of the interposer 140, eight second semiconductor components 120b that are spaced apart from one another are arranged in two rows and beside the first semiconductor component 120a, and the first semiconductor component 120a that is located between the second semiconductor components 120b has a size larger than the size of each of the second semiconductor components 120b.

In some embodiments, either the first semiconductor component 120a or the second semiconductor component 120b is or includes a logic die, a memory die, a large-scale system die or even a package subunit. In some embodiments, at least one of the first semiconductor component 120a and the second semiconductor component 120b includes a system-on-chip (SoC) die, and at least one of the second semiconductor components 120b include a memory die such as a high-bandwidth-memory (HBM) die. In some embodiments, the first semiconductor component 120a includes a single device die or a plurality of device dies bonded together to form a system. The logic dies are or include Central Processing Unit (CPU) dies, Graphic Processing Unit (GPU) dies, Application Specific Integrated Circuit (ASIC) dies, Field Programmable Gate Array (FPGA) dies, or combinations thereof. In some embodiments, the second semiconductor component 120b includes a memory cube with multiple memory chips 122 stacked on a base chip 121 for controlling operation of the stacked memory chips. The second semiconductor components 120b may be configured as dynamic random access memories (DRAMs), resistive random access memories (RRAMs), static random access memories (SRAMs), or other types of memories. In some embodiments, the first semiconductor component 120a and the second semiconductor component(s) 120b may be different types of dies or perform different functions. In other embodiments, the first semiconductor component 120a and the second semiconductor component(s) 120b may be the same type of dies or perform the same functions. Even though one first semiconductor component 120a and several second semiconductor component(s) 120b are shown in FIG. 1C, it is understood that multiple first semiconductor components 120a and multiple second semiconductor components 120b are included, and the number of the components or dies included in the semiconductor package is not limited by the embodiments herein. In some embodiments, the connectors 165 include micro-bumps, copper pillars, stud bumps, or the like.

In some embodiments, the interposer 140 is or includes a semiconductor material interposer such as silicon interposer with through semiconductor vias. In some embodiments, the interposer 140 is or includes an organic interposer. In some embodiments, the interposer 140 is or includes glass, ceramic, glass-epoxy, glass polyimide, or even embedded with one or more interconnect element or die. Although not explicit illustrated in the figures, the interposer 140 may include metallization including metal lines or layers and metal vias for electrical connection and such electrical connection are illustrated as connecting lines in the figures.

Furthermore, referring to FIG. 1A, the package component 12 further includes an underfill 180 filled between the interposer 140 and the first and second semiconductor components 120a, 120b and between the first and second semiconductor components 120a, 120b and surrounding the connectors 165. The underfill 180 fills the gap between the first and second semiconductor components 120a, 120b and the interposer 140 to laterally encapsulate the connectors 165. The material of the underfill 180 may be or include epoxy resin or other suitable dielectric materials. In some embodiments, the package component 12 includes an insulating encapsulation 190 disposed on the interposer 140 to laterally wrap the first and second semiconductor components 120a, 120b and the underfill 180. As illustrated in FIG. 1A, the sidewalls of the insulating encapsulation 190 are substantially aligned with the sidewalls of the interposer 140. In some embodiments, the package component 12 is electrically connected with the package substrate 110 through the conductive terminals 170 disposed between the bottom surface of the interposer 140 and the top surface of the package substrate 110. In some embodiments, the conductive terminals 170 include controlled collapse of chip connection bumps (C4 bumps), metal pillars, metal pillars with solder thereon, metal bumps or solder bumps, and may be formed through any suitable method such as evaporation, electroplating, printing, solder transfer, ball placement, or the like.

As illustrated in FIG. 1A, after bonding the package component 12 to the package substrate 110, the first and second semiconductor components 120a, 120b of the package component 12 are electrically connected to the package substrate 110 through the conductive terminals 165, the interposer 140, and the conductive terminals 170.

Referring to both FIG. 1B and FIG. 1C, an affixture structure 130 is provided and affixed to the semiconductor package structure 100P (FIG. 1A) to form a semiconductor package structure 100. After adding the affixture structure 130, the slightly warped semiconductor package structure 100P is counterbalanced and exhibits a less warped or nearly flat form. Referring to FIG. 1B, the affixture structure 130 is connected to and fixed to a peripheral portion 110P of the package substrate 110 for counterbalancing the stress and reducing the warpage of the package structure. Herein, without using the adhesives, screws or bolts, the affixture structure 130 is permanently fixed to the package substrate 110 through a tight-fitting mechanism, a close-fitting means, clinch joining, snap-fitting or complimentary configuration-fitting mechanisms. In some other embodiments, temporary addition structures may be utilized and then removed or detached depending on the product requirements.

Referring to FIG. 1B and FIG. 1C again, the affixture structure 130 includes at least two first portions 132, and the two first portions 132 are beam-shaped portions each having a channel or recess 133 extending through the entire beam-shaped portion (extending along the length direction of the beam) for receiving and clamping to the two opposing first sides S1 of the package substrate 110. In other words, the first portion 132 may be shaped as a channel beam or a C-beam (with a C-shaped cross-section), and the recess 133 is shaped as the groove open at one side with a void space. Depending on the design or the shape of the package substrate 110, the shape, dimensions and outline of the recess 133 or the design of the affixture structure may be modified accordingly. Referring to FIG. 1B, the peripheral portion 110P at the two opposing first sides S1 of the package substrate 110 are inserted into the recesses 133 of the first portions 132 and are fitted into the two recesses 133 respectively. In FIG. 1B, the lateral configuration of the package substrate 110 and the cross-sectional shape of the recess 133 are exemplarily depicted as rectangular and four sided for illustration purposes. For each recess 133, at least the inner sidewall 133S of the recess 133 is in direct contact with the lateral side surface 115 at either first side S1, either the upper surface 133T is in contact with a portion of the first surface 111 of the package substrate 110 or the lower surface 133B of the recess 133 is in contact with a portion of the second surface 113 of the package substrate 110. In some embodiments, when the semiconductor package structure 100P exhibits the frowning-convex warpage form, the recesses 133 directly contact the second surface 113 of the peripheral portion 110P as well as the lateral side surfaces 115 of the package substrate 110. In some embodiments, the recesses 133 directly contact the first surface 111 and the second surface 113 of the peripheral portion 110P as well as the lateral side surfaces 115 of the package substrate 110. In some embodiments, the peripheral portion 110P and the first portions 132 may work as snap fit joints by inserting the protruding part (i.e. the peripheral portion 110P) into the recessed region (the recesses 133 of the first portions 132), and the recessed region locking onto the protruding part, so that a secure fit is achieved.

In FIG. 1B, the first portion 132 is securely engaged with and locked with the peripheral portion 110P of the package substrate 110, and the first portion 132 covers the peripheral portion 110P (in contact with the side surface 115) like a fence wall.

Furthermore, referring to FIG. 1C and FIG. 1D, after affixing the first portions 132, at least two second portions 134 of the affixture structure 130 are joined and locked with the two first portions 132 respectively (the hollow arrows show the assembling directions). In some embodiments, the two second portions 134 are in contact with the lateral side surfaces 115 at the two opposing second sides S2 of the package substrate 110. In some embodiments, the two second portions 134 are timber or beam-shaped portions without channel or recess formed therein. Compared with the first portions 132 with the recesses 133 and functioning as locking portions to be locked with the peripheral portion 110P, the second portions 134 that merely touch the lateral side surfaces 115 but are not locked with the peripheral portion 110P function as the linking portions for joining with the two first portions 132. In some embodiments, the two second portions 134 are assembled with the two first portions 132 to form a ring-like or a frame-like affixture structure 130.

In some embodiments, through the locking of the first portions 132, the affixture structure 130 is fixed to the package substrate 110 and the affixture structure 130 contacts and surrounds the lateral side surfaces 115 of the package substrate 110. Through the addition of the affixture structure 130, the warpage of the semiconductor package structure 100 can be alleviated and suppressed, and the yield and the reliability of the package structure are enhanced. It is possible that more or less first portions 132 and more or less second portions 134 are included in the affixture structure 130, and the package substrate 110 may be provided in a different shape such as a round shape, an oval shape, or a polygonal shape.

In more detail, each of the two first portions 132 includes first engaging portions 135, each of the two second portions 134 includes second engaging portions 137, and the individual first engaging portion 135 engages with the individual second engaging portion 137 to connect and join the first portions 132 with the second portions 134. For example, the first engaging portion 135 includes a protruded block and the second engaging portion 137 include a recessed cavity or hole (or vice versa), and the pair of the portions 135/137 works as mortise and tenon joint. In some embodiments, the shapes and the functions of the first engaging portions 135 and the second engaging portions 137 may be switched as long as the first and second portions are assembled and joined. In some embodiments, the shape of the engaging hole and the shape of the engaging block may be rectangular in the top views. In some embodiments, the shapes and the number of the engaging portions are merely exemplary and are not intended to limit the scope of the disclosure. In some other embodiments, the first portions 132 and the second portions 134 may be assembled through other assembly methods, such as screw fastening.

Referring back to FIG. 1B again, each of the first portions 132 has a thickness T, each of the recesses 133 has a depth D, and the depth D is about or greater than half of the thickness T. In some embodiments, the thickness T of each of the first portions 132 ranges from about 6 millimeters (mm) to about 15 mm or about 8 mm, and the depth D of the recesses 133 is about 3 mm to about 12 mm with the thickness T1 measuring from the sidewall 133S of the recess 133 is about 3 mm. In some embodiments, the depth D′ is different from the depth D due to the placement of the connective terminals 150. In some embodiments, the depth D of the recesses 133 is about 3 mm to about 12 mm, and the depth D′ of the recesses 133 is about 0.5 mm to about 3 mm. For the first portion 132 having an upper surface 131 and a lower surface 139 opposite to the upper surface 131, the above height L1 (distance from the upper surface 131 to the first surface 111 of the package substrate 110) of the first portion 132 is greater than the below height L2 (distance from the lower surface 139 to the second surface 113 of the package substrate 110) of the first portion 132. That is, for counterbalancing the warpage, a larger part of the first portion 132 is located above the surface 111 of the package substrate 110, and a smaller part of the first portion 132 is located below the surface 113 of the package substrate 110. In some embodiments, after assembling the affixture structure 130, the upper surface 131 of the first portion 132 is higher than the backside surface of the package component 12. In some other embodiments, the upper surface 131 of the first portion 132 is about leveled with the backside surface of the package component 12, or even lower than the backside surface of the package component 12. In some embodiments, the ratios of the height L1 to the height L2 is about 5~15. It is understood that the L1/L2 ratio may be tuned depending on the warpage level of the package substrate 110 to effectively minimize the warpage of the whole package structure.

In some embodiments, a material of the first portions 132 is different from a material of the second portions 134. In some embodiments, a material of the first portions 132 is the same as a material of the second portions 134. The affixture structure 130 may provide sufficient rigidity and/or thermal conductivity depending on the material selected. In some embodiments, a material of the first portions 132 and a material of the second portions 134 respectively include copper, aluminum, molybdenum, steel, stainless steels such as alloys of iron and chromium (e.g. SUS430), alloys of iron, chromium and nickel (e.g. SUS 304), metal alloys such as a nickel-iron alloy with 42 wt. % of nickel (alloy 42), combinations thereof, and/or other suitable material(s). In some embodiments, the rigidity of the first portions 132 is higher than the rigidity of the second portions 134. In some embodiments, the rigidity of the second portions 134 is higher than the rigidity of the first portions 132. In some embodiments, the thermal conductivity of the second portions 134 is greater than the thermal conductivity of the first portions 132. In some embodiments, the thermal conductivity of the second portions 134 is the same as the thermal conductivity of the first portions 132.

As the affixture structure 130 is to lessen or suppress the warpage of the package substrate 110 without affecting its electrical connection with other components, the affixture structure 130 is not electrically connected with the package substrate 110 and the package component 12, and the affixture structure 130 contacts the insulating layers or dielectric layers 114a, 116a of the package substrate 110 without contacting any conductive or metallic patterns of the package substrate 110. In some embodiments, without using adhesives for joining, the affixture structure 130 may be assembled as a frame structure for the semiconductor package structure 100 for warpage control.

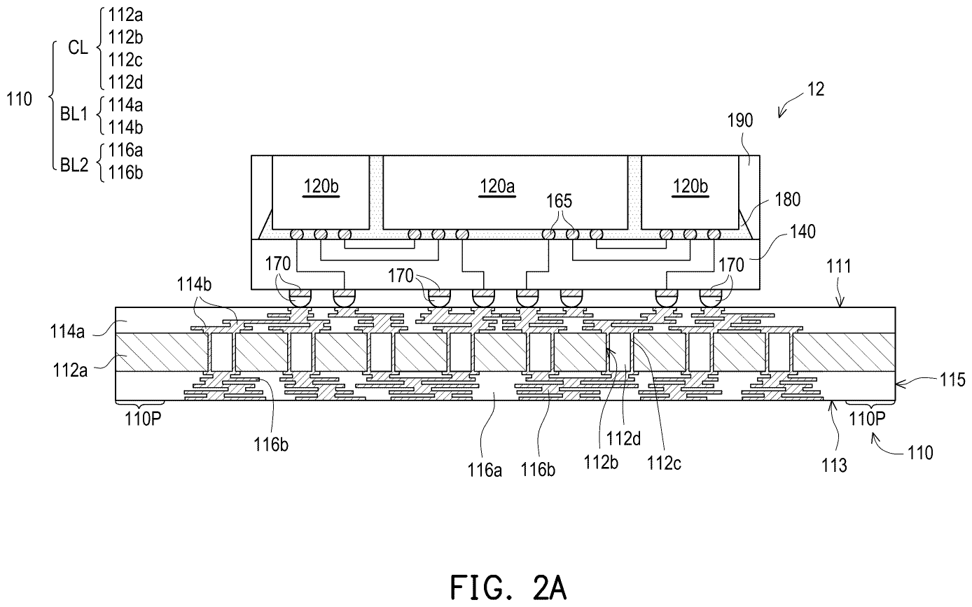

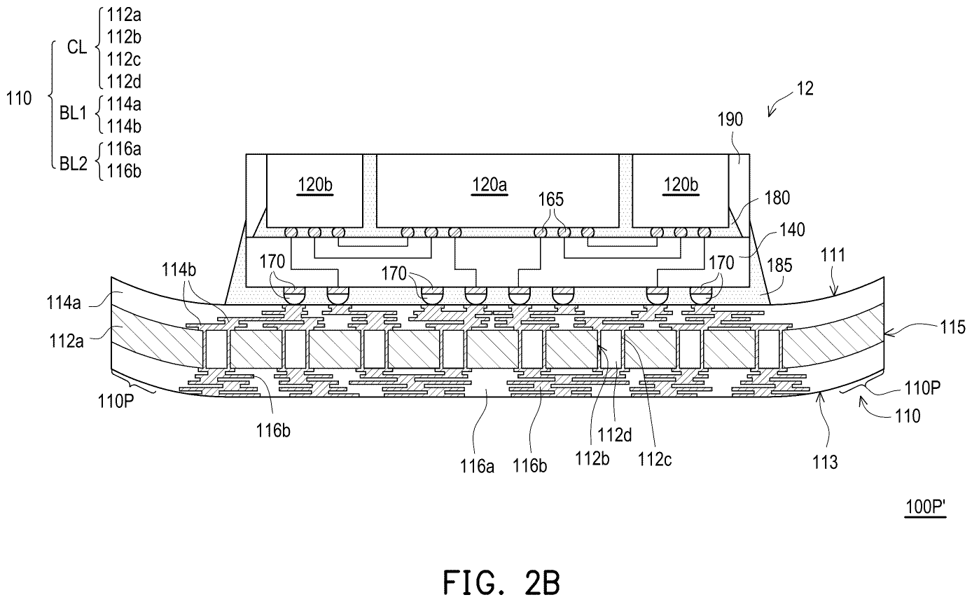

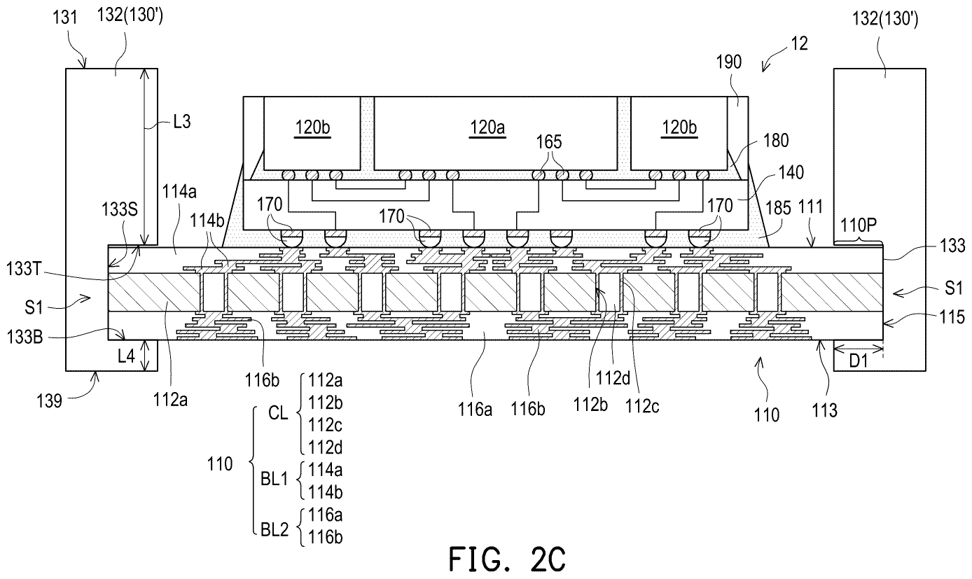

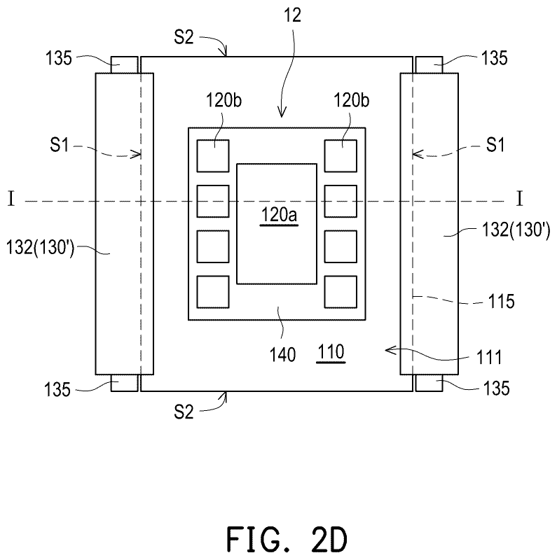

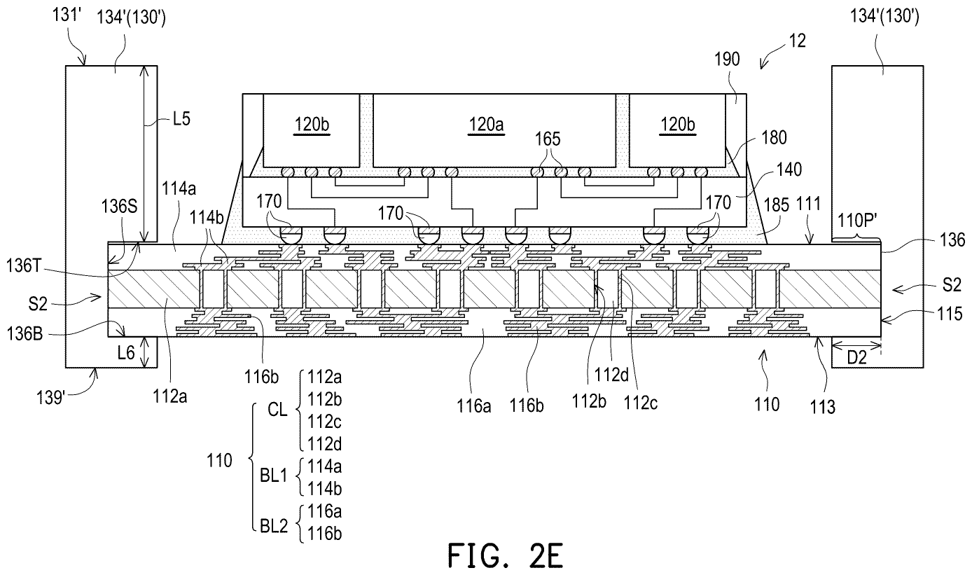

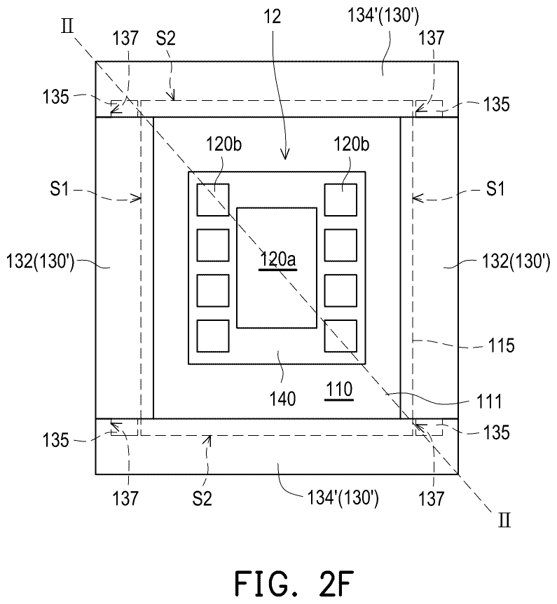

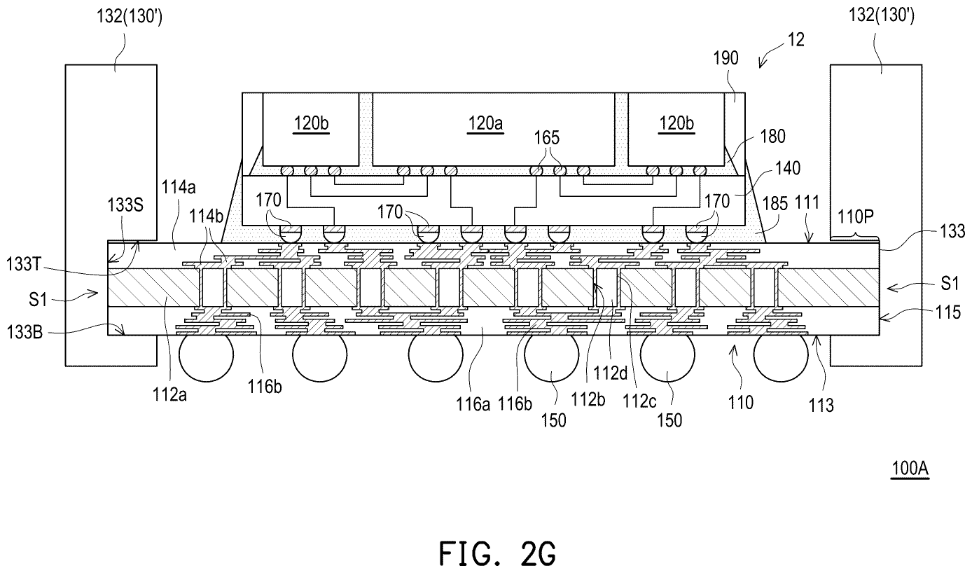

FIGS. 2A-2G are schematic cross-sectional views and top views illustrating various stages of a manufacturing method of a semiconductor package in accordance with some embodiments of the disclosure. For clarity of explanation, FIG. 2A to FIG. 2C, FIG. 2E, and FIG. 2G are exemplary cross-sectional views, and FIG. 2D and FIG. 2F are exemplary top views of FIG. 2C and FIG. 2E, respectively. FIG. 2C is an exemplary cross-sectional view along the cross-sectional line I-I in FIG. 2D. FIG. 2E is an exemplary cross-sectional view along the cross-sectional line II-II in FIG. 2F. For simplification purposes, certain components such as the underfill and the insulating encapsulation may be omitted in FIG. 2D and FIG. 2F. The same or similar elements will be labelled with the same reference numbers or labels in the figures, and detailed descriptions will not be repeated for simplification purposes. It is understood that the same or similar functions, formation methods and materials may be applied for the same or similar elements.

In the process, referring to FIG. 2A, firstly, one or more the package components 12 are mounted on the package substrate 110 and are bonded to the package substrate 110 through the conductive terminals 170. Similarly, the package component 12 includes the interposer 140, at least one first semiconductor component 120a disposed on the interposer 140, and several second semiconductor components 120b arranged beside the first semiconductor component 120a and disposed on the interposer 140. The first semiconductor component(s) 120a and the second semiconductor component(s) 120b are electrically connected with the interposer 140 through the connectors 165, and the first semiconductor component(s) 120a and the second semiconductor component(s) 120b are electrically connected through the interposer 140. As shown in FIG. 2A, the underfill 180 is filled between the interposer 140 and the first and second semiconductor components 120a, 120b and between the first and second semiconductor components 120a, 120b and surrounding the connectors 165, and the insulating encapsulation 190 laterally wraps the first and second semiconductor components 120a, 120b and the underfill 180.

Next, referring to both FIG. 2A and FIG. 2B, after bonding the package component 12 to the package substrate 110 through performing a thermal process, an underfill 185 is formed between the interposer 140 and the package substrate 110 and surrounds the conductive terminals 170. The underfill 185 fills the gap between the interposer 140 and the package substrate 110 to laterally encapsulate the conductive terminals 170. The material of the underfill 185 may include epoxy resins or other suitable dielectric materials. In some embodiments, the underfill 185 covers sidewalls of the interposer 140 as well as lower portions of sidewalls of the insulating encapsulation 190. As shown in FIG. 2B, in some embodiments, after bonding the package component 12 to the package substrate 110, the package structure 100P′ may be slightly warped and exhibits a smile-concave warpage form. It is understood that the warpage level shown in FIG. 2B is merely exemplary and various warpage levels including symmetrical or unsymmetrical warpage over the whole package substrate may be presented.

Next, referring to FIG. 2B, FIG. 2C and FIG. 2D, the affixture structure 130′ is provided and affixed to the semiconductor package structure 100P'. After adding the affixture structure 130', the slightly warped semiconductor package structure 100P′ is counterbalanced and exhibits a less warped or nearly flat form. The affixture structure 130′ is connected to and fixed to the peripheral portion 110P of the package substrate 110 for counterbalancing the stress and reducing the warpage of the package structure. Herein, without using the adhesives, screws or bolts, the affixture structure 130′ is securely fixed to the package substrate 110 through a tight-fitting mechanism, a close-fitting means, clinch joining, snap-fitting or complimentary configuration-fitting mechanisms. In some other embodiments, temporary addition structures may be utilized and then removed or detached depending on the product requirements.

In more detail, the affixture structure 130′ includes at least two first portions 132, and the two first portions 132 are beam-shaped portions each having a channel or groove like recess 133 extending through the entire beam-shaped portion (extending along the length direction of the beam) for receiving and clamping to the two opposing first sides S1 of the package substrate 110. In other words, the first portion 132 may be shaped as a channel beam or a C-beam (with a C-shaped cross-section). For example, for the first portions 132, each recess 133 may have a depth D1, and the depth D1 is about or greater than half of the thickness of the first portion 132. Depending on the design or the shape of the package substrate 110, the shape, dimensions and outline of the recess 133 or the design of the affixture structure 130′ may be modified accordingly.

Referring to FIG. 2C, the peripheral portion 110P at the two opposing first sides S1 of the package substrate 110 are inserted into the open grooves of the recesses 133 of the first portions 132 and are fitted into the two recesses 133 respectively. In FIG. 2C, the lateral configuration of the package substrate 110 and the cross-sectional shape of the recess 133 are exemplarily depicted as rectangular and four sided for illustration purposes. For securely engaging, at least two surfaces of the peripheral portion 110P are in direct contact with the recess 133. For each recess 133, at least the inner sidewall 133S of the recess 133 is in direct contact with the lateral side surface 115 at either first side S1, and either the upper surface 133T is in contact with a portion of the first surface 111 of the package substrate 110 or the lower surface 133B of the recess 133 is in contact with a portion of the second surface 113 of the package substrate 110. In some embodiments, when the semiconductor package structure 100P′ exhibits the smile-concave warpage form as shown in FIG. 2B, the recesses 133 directly contact the first surface 111 of the peripheral portion 110P as well as the lateral side surfaces 115 of the package substrate 110. As the inner sidewall 133S of the recess 133 is in direct contact with the lateral side surface 115, the depth D1 of the recess 133 may be regarded as the width or distance of the peripheral portion 110P. In some embodiments, either recess 133 directly contacts the first surface 111 and the second surface 113 of the peripheral portion 110P as well as the lateral side surface 115 of the package substrate 110. In some embodiments, the peripheral portion 110P and the first portions 132 may work as snap fit joints by inserting the protruding part (i.e. the peripheral portion 110P) into the recessed region (the recesses 133 of the first portions 132), the recessed region locking onto the protruding part, so that a secure fit is achieved.

In more detail, for the first portion 132 having an upper surface 131 and a lower surface 139 opposite to the upper surface 131, the above height L3 (distance from the upper surface 131 to the first surface 111 of the package substrate 110) of the first portion 132 is greater than the below height L4 (distance from the lower surface 139 to the second surface 113 of the package substrate 110) of the first portion 132. In some embodiments, after assembling the affixture structure 130, the upper surface 131 of the first portion 132 is higher than the backside surface of the package component 12. In some embodiments, the ratios of the height L3 to the height L4 is about 5~15. It is understood that the L3/L4 ratio may be tuned depending on the warpage level of the package substrate 110 to effectively minimize the warpage of the whole package structure.

In addition, each first portion 132 includes first engaging portions 135 located at two opposite ends of the first portion. For example, the first engaging portion 135 includes a protruded block protruding from the end of the beam-shaped body with a smaller size (e.g. tenon or tongue). In some other embodiments, the first portions 132 and the corresponding first engaging portions 135 are integrally formed, meaning that the first portions 132 and the corresponding first engaging portions 135 are made of the same material. In some other embodiments, the material of the first portions 132 is different from the material of the plurality of first engaging portions 135.

Next, referring to FIG. 2E and FIG. 2F, after affixing the first portions 132, two second portions 134′ of the affixture structure 130′ are joined and locked with the two first portions 132 respectively. The two second portions 134′ are beam-shaped portions each having a channel or groove like recess 136 extending through the entire beam-shaped portion (extending along the length direction of the beam) for accommodating and clamping to the two opposing second sides S2 of the package substrate 110. In other words, the second portion 134′ may be shaped as a channel beam or a C-beam (with a C-shaped cross-section), and the recess 136 is shaped as the groove open at one side with a void space. For example, for the second portions 134′, each recess 136 may have a depth D2. The depth D2 may about half of the thickness of the second portion 134′, or less than half of the thickness of the second portion 134′. Alternatively, the depth D2 may about greater than half of the thickness of the second portion 134′. Depending on the design or the shape of the package substrate 110, the shape, dimensions and outline of the recess 136 or the design of the affixture structure 130′ may be modified accordingly. In some embodiments, the recesses 133 and 136 are formed with different dimensions, and the depth D2 is different from the depth D1.

Referring to FIG. 2E, the peripheral portion 110P′ at the two opposing second sides S2 of the package substrate 110 are inserted into the recesses 136 of the second portions 134′ and are fitted into the two recesses 136 respectively. In FIG. 2E, the lateral configuration of the package substrate 110 and the cross-sectional shape of the recess 136 are exemplarily depicted as rectangular and four sided for illustration purposes. For each recess 136, at least the inner sidewall 136S of the recess 136 is in direct contact with the lateral side surface 115 at either second side S2, either the upper surface 136T is in contact with a portion of the first surface 111 of the package substrate 110 or the lower surface 136B of the recess 136 is in contact with a portion of the second surface 113 of the package substrate 110. In some embodiments, when the semiconductor package structure 100P′ exhibits the smile-concave warpage form as shown in FIG. 2B, the recesses 136 directly contact the first surface 111 of the peripheral portion 110P′ as well as the lateral side surfaces 115 of the package substrate 110. In some embodiments, the recesses 136 directly contact the first surface 111 and the second surface 113 of the peripheral portion 110P′ as well as the lateral side surface 115 of the package substrate 110. In some embodiments, the peripheral portion 110P′ and the second portions 134′ may work as snap fit joints by inserting the protruding part (i.e. the peripheral portion 110P′) into the recessed region (the recesses 136 of the second portions 134′), and the recessed region locking onto the protruding part, so that a secure fit is achieved.

In more detail, for the second portion 134′ having an upper surface 131′ and a lower surface 139′ opposite to the upper surface 131′, the above height L5 (distance from the upper surface 131′ to the first surface 111 of the package substrate 110) of the second portion 134′ is greater than the below height L6 (distance from the lower surface 139′ to the second surface 113 of the package substrate 110) of the second portion 134′. That is, for counterbalancing the warpage, a larger part of the second portion 134′ is located above the surface 111 of the package substrate 110, and a smaller part of the second portion 134′ is located below the surface 113 of the package substrate 110. In some embodiments, after assembling the affixture structure 130', the upper surface 131′ of the second portion 134′ is higher than the backside surface of the package component 12. In some other embodiments, the upper surface 131′ of the second portion 134′ is about leveled with the backside surface of the package component 12, or even lower than the backside surface of the package component 12. In some embodiments, the ratios of the height L5 to the height L6 is about 5~15. In some embodiments, the above height L5 of the second portion 134′ is different from the above height L3 of the first portion 132. In some embodiments, the below height L6 of the second portion 134′ is different from the below height L4 of the first portion 132. In some embodiments, the above height L5 and the below height L6 of the second portion 134′ are different from the above height L3 and the below height L4 of the first portion 132. In some embodiments, the L3/L4 ratio is different from the L5/L6 ratio. It is understood that the L5/L6 ratio may be tuned depending on the warpage level of the package substrate 110 to effectively minimize the warpage of the whole package structure.

In addition, each second portions 134′ includes second engaging portions 137. For example, the second engaging portion 137 includes one or more recessed cavities or holes concave from the end of the beam-shaped body with a smaller size (e.g. mortise or groove).

Referring to FIG. 2F again, the individual first engaging portion 135 engages with the individual second engaging portion 137 to connect and join the first portions 132 with the second portions 134′. The pair of the portions 135/137 works as mortise and tenon joints or tongue and groove joints. In some embodiments, the shapes and the functions of the first engaging portions 135 and the second engaging portions 137 may be switched as long as the first and second portions 132, 134′ are assembled and joined. In some embodiments, the shape of the engaging hole and the shape of the engaging block may be rectangular in the top views. In some embodiments, the shapes and the number of the engaging portions are merely exemplary and are not intended to limit the scope of the disclosure. In some embodiments, the second portions 134′ are assembled with the first portions 132 to form a ring-like or a frame-like affixture structure 130′. In some other embodiments, the first portions 132 and the second portions 134′ may be assembled with each other through other assembly methods, such as screw fastening.

Herein, the affixture structure 130′ is affixed to the package substrate 110 in two stages, by affixing the first portions 132 to the peripheral portion 110P of the package substrate 110 from the two opposing sides S1 of the package substrate 110 and affixing the second portions 134′ to the peripheral portion of the package substrate 110 from another two opposing sides S2 of the package substrate 110. In some embodiments, the recesses 133 of the first portions 132 at least contact the side surface 115 and one surface of the first surface 111 and the second surface 113 of the package substrate 110, and the recesses 136 of the second portions 134′ at least contact the side surface 115 and one surface of the first surface 111 and the second surface 113 of the package substrate 110. The plurality of first engaging portions 135 respectively engages with the plurality of second engaging portions 137 to connect the first portions 132 with the second portions 134'. The affixture structure 130′ is fixed to a peripheral portion of the package substrate 110 and surrounds the lateral side surfaces 115 of the package substrate 110 for counterbalancing the stress and reducing the warpage.

Finally, referring to FIG. 2G, connective terminals 150 are formed on the second surface 113 of the package substrate 110 to form the semiconductor package structure 100A. The connective terminals 150 may allow the package substrate 110 to be securely mounted on a board substrate such as a printed circuit board (PCB) and electrically coupled to the board substrate. In some embodiments, the connective terminals 150 are electrically connected to the package component 12 via the package substrate 110.

Through the addition of the affixture structure 130′, the warpage of the semiconductor package structure 100A can be alleviated and suppressed, and the yield and the reliability of the package structure are enhanced.

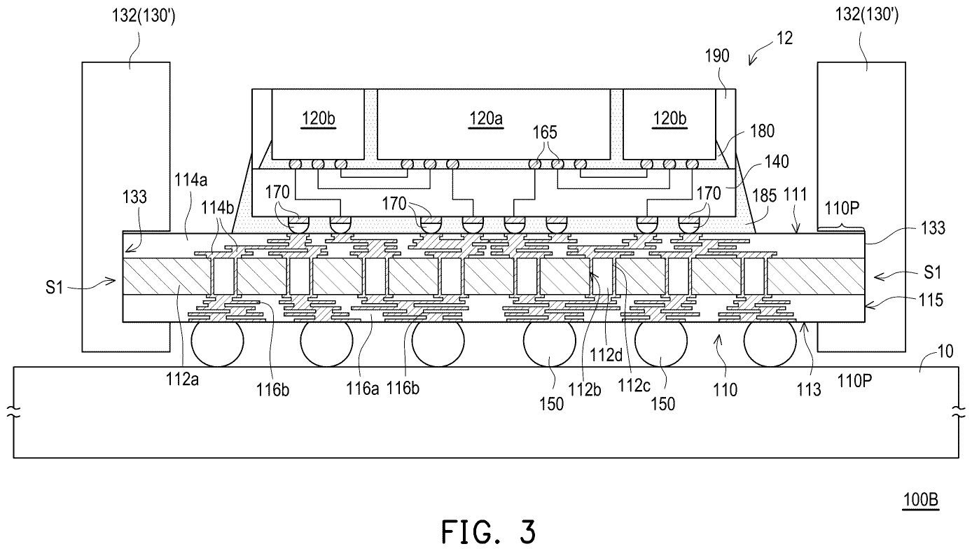

FIG. 3 is schematic cross-sectional views illustrating package structures in accordance with some embodiments of the disclosure. In some embodiments, referring to FIG. 3, the semiconductor package structure 100A (or semiconductor package structure 100) is bonded to a printed circuit board (PCB) 10 after the affixture structure 130′ (or the affixture structure 130) is fixed to the peripheral portion of the package substrate 110. The plurality of connective terminals 150 may constitute a ball-grid array (BGA) that may allow the semiconductor package structure to be securely mounted (e.g., by surface mount technology (SMT)) on the PCB 10 and electrically coupled to the PCB 10 to form the semiconductor package structure 100B. As shown in FIG. 3, the affixture structure 130′ is distanced from and spaced apart from the PCB 10 and is not electrically connected or coupled with the PCB 10.

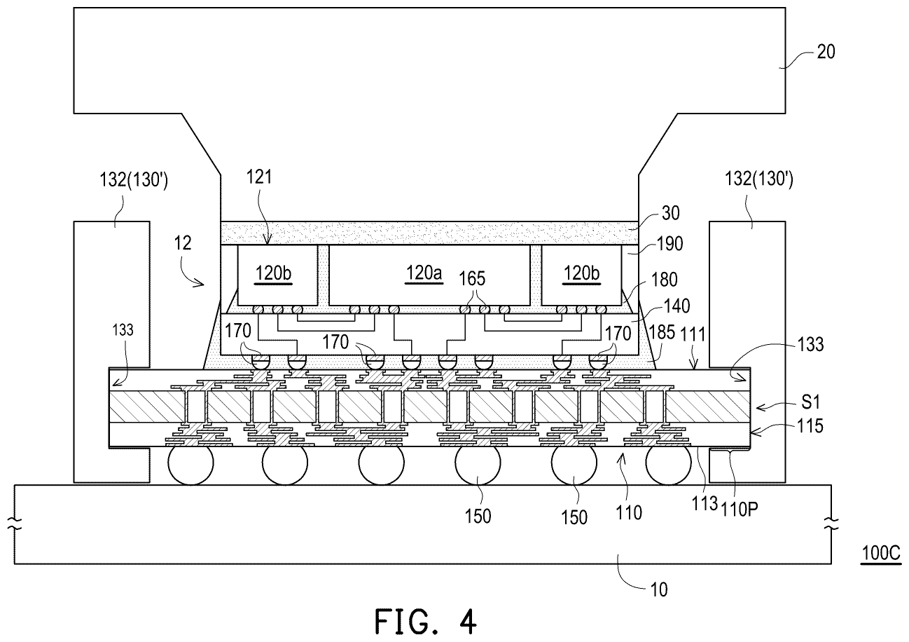

FIG. 4 is schematic cross-sectional views illustrating package structures in accordance with some embodiments of the disclosure. In some embodiments, referring to FIG. 4, a heat dissipating component 20 (e.g., heat sink, heat spreader, or the like) is attached to the semiconductor package structure 100B and disposed on the back surface 121 of the package component 12 to enhance heat dissipation to obtain a semiconductor package structure 100C. The heat dissipating component 20 is attached to the back surface 121 of the package component 12 through a thermal interface material (TIM) 30. In some embodiments, the heat dissipating component 20 is distanced from and spaced apart from the affixture structure 130′, and there is no direct/physical contact between the heat dissipating component 20 and the affixture structure 130′.

According to some embodiments, a semiconductor package structure includes a package substrate, a packaging component and an affixture structure. The package substrate has a first surface, a second surface opposite to the first surface and a side surface connecting the first surface and the second surface. The packaging component is disposed on the first surface of the package substrate and electrically connected to the package substrate. The affixture structure is affixed to a peripheral portion of the package substrate, wherein the affixture structure at least contacts the side surface and one surface of the first surface and the second surface of the package substrate.

According to some embodiments, a semiconductor package structure includes a package substrate, a packaging component and an affixture structure. The package substrate has a top surface and a bottom surface and lateral surfaces connecting the top and bottom surfaces. The packaging component is disposed on the top surface of the package substrate and electrically connected to the package substrate. The affixture structure is fixed to a peripheral portion of the package substrate and contacting lateral surfaces of the package substrate, wherein a first portion of the affixture structure with a first recessed groove is engaged with the peripheral portion of the package substrate, extends from the top surface of the package substrate with a first distance and extends from the bottom surface of the package substrate with a second distance.

According to some embodiments, a manufacturing method of a semiconductor package structure includes providing a package substrate with a first surface, a second surface and a side surface connecting the first and second surfaces; providing a package component and mounting the package component to the first surface of the package substrate; bonding the package component to the package substrate, wherein the package component is disposed on the first surface of the package substrate and electrically connected to the package substrate; and providing an affixture structure and affixing the affixture structure to the package substrate, wherein providing the affixture structure comprises: providing a first portion of the affixture structure with a first recessed groove to engage with a peripheral portion of the package substrate by inserting the peripheral portion into the first recessed groove, wherein the first recessed groove at least contacts the side surface and one surface of the first surface and the second surface of the package substrate to securely fix the first portion to the peripheral portion; and providing a second portion of the affixture structure and joining the second portion with the first portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a package substrate having a first surface, a second surface opposite to the first surface and a side surface connecting the first surface and the second surface;
a packaging component disposed on the first surface of the package substrate and electrically connected to the package substrate; and
an affixture structure affixed to a peripheral portion of the package substrate, wherein the affixture structure at least contacts the side surface and one surface of the first surface and the second surface of the package substrate.

2. The semiconductor package structure of claim 1, wherein the affixture structure comprises first portions with first recesses, the first recess has a third surface and a four surface opposite to the third surface and an inner sidewall connecting the third and fourth surfaces, the peripheral portion is engaged with the first recesses, and the inner sidewalls and the third and fourth surfaces of the first recesses are in contact with the side surface and the one surface of the package substrate.

3. The semiconductor package structure of claim 2, wherein the affixture structure further comprises second portions joined with the first portions and contacting only the side surface of the package substrate.

4. The semiconductor package structure of claim 3, wherein the first portions comprise first engaging blocks, the second portions comprise second engaging holes, and the first engaging blocks respectively interlock with the second engaging holes to connect the first portions with the second portions.

5. The semiconductor package structure of claim 2, wherein the affixture structure further comprises second portions with second recesses and joined with the first portions, the second recess has a fifth surface and a sixth surface opposite to the fifth surface and an inner sidewall connecting the fifth and sixth surfaces, the peripheral portion is engaged with the second recesses, and the inner sidewalls and the fifth and sixth surfaces of the second recesses are in contact with the side surface and the one surface of the package substrate.

6. The semiconductor package structure of claim 5, wherein the first portions comprise first engaging blocks, the second portions comprise second engaging holes, and the first engaging blocks respectively interlock with the second engaging holes to connect the first portions with the second portions.

7. The semiconductor package structure of claim 1, wherein the package component comprises a first semiconductor component and second semiconductor components, and the first semiconductor component is located between the second semiconductor components, and the first semiconductor component functions differently from the second semiconductor component.

8. The semiconductor package structure of claim 7, wherein the package component further includes an interposer disposed below the first and second semiconductor components and located between the first and second semiconductor components and the package substrate.

9. A semiconductor package structure, comprising:
a package substrate having a top surface and a bottom surface and lateral surfaces connecting the top and bottom surfaces;
a package component disposed on the top surface of the package substrate and electrically connected to the package substrate; and
an affixture structure fixed to a peripheral portion of the package substrate and contacting lateral surfaces of the package substrate, wherein a first portion of the affixture structure with a first recessed groove is engaged with the peripheral portion of the package substrate, extends from the top surface of the package substrate with a first distance and extends from the bottom surface of the package substrate with a second distance.

10. The semiconductor package structure of claim 9, wherein the affixture structure further includes a second portion with a second recessed groove, and the second portion with the second recessed groove is engaged with the peripheral portion of the package substrate, extends from the top surface of the package substrate with a third distance and extends from the bottom surface of the package substrate with a fourth distance.

11. The semiconductor package structure of claim 10, wherein a ratio of the first distance to the second distance is different from a ratio of the third distance to the fourth distance.

12. The semiconductor package structure of claim 10, wherein the affixture structure comprises at least two first portions and at least two second portions, and the at least two first portions are located at two opposing first sides of the package substrate, and the at least two second portions are located at two opposing second sides of the package substrate.

13. The semiconductor package structure of claim 12, wherein the at least two first portions are joined with the at least two second portions to form a frame-shape structure surrounding the lateral surfaces of the package substrate.

14. The semiconductor package structure of claim 10, wherein the first recessed groove has a first depth different from a second depth of the second recessed groove.

15. The semiconductor package structure of claim 10, wherein the first portion includes one or more engaging blocks, and the second portion includes one or more engaging holes, and the first portion is joined with the second portion through engagement of the engaging blocks and the engaging holes.

16. The semiconductor package structure of claim 9, wherein the affixture structure further includes a second portion joined with the first portion, and the second portion is in contact with one lateral surface of the package substrate without contacting the top and bottom surfaces.

17. The semiconductor package structure of claim 16, wherein the first portion includes one or more engaging blocks, and the second portion includes one or more engaging holes, and the first portion is joined with the second portion through engagement of the engaging blocks and the engaging holes.

18. The semiconductor package structure of claim 9, wherein the package component comprises a first semiconductor component, second semiconductor components located beside the first semiconductor component, and an interposer disposed below the first and second semiconductor components, and the first semiconductor component functions differently from the second semiconductor components.

19. A manufacturing method of a semiconductor package structure, comprising:
providing a package substrate with a first surface, a second surface and a side surface connecting the first and second surfaces;
providing a package component and mounting the package component to the first surface of the package substrate;
bonding the package component to the package substrate, wherein the package component is disposed on the first surface of the package substrate and electrically connected to the package substrate; and
providing an affixture structure and affixing the affixture structure to the package substrate, wherein providing the affixture structure comprises:
providing a first portion of the affixture structure with a first recessed groove to engage with a peripheral portion of the package substrate by inserting the peripheral portion into the first recessed groove, wherein the first recessed groove at least contacts the side surface and one surface of the first surface and the second surface of the package substrate to securely fix the first portion to the peripheral portion; and
providing a second portion of the affixture structure and joining the second portion with the first portion.

20. The manufacturing method of the semiconductor package structure of claim 19, wherein the package substrate has two opposing first sides and two opposing second sides connecting the two opposing first sides, providing the affixture structure comprises providing at least two first portions with the first recessed grooves and inserting the peripheral portion into the first recessed grooves to affix the at least two first portions to the two opposing first sides of the package substrate, providing at least two second portions with second recessed grooves, and inserting the peripheral portion into the first recessed grooves to affix the at least two second portions to the two opposing second sides of the package substrate.
